(19) United States
(12) Patent Application Publication
(10) Pub. No.: US 2025/0210613 A1
(43) Pub. Date: Jun. 26, 2025

(54) DIRECT APPLIED INTERPOSER FOR CO-PACKAGED OPTICS

(71) Applicant: Applied Materials, Inc., Santa Clara, CA (US)

(72) Inventor: Guan-Shian CHEN, Sunnyvale, CA (US)

(21) Appl. No.: 18/391,776

(22) Filed: Dec. 21, 2023

(51) Int. Cl. H01L 25/00; H01L 21/48; H01L 21/56; H01L 21/66; H01L 23/538; H01L 23/544; H01L 25/065; H01L 25/18

(52) U.S. Cl. CPC H01L 25/50; H01L 21/486; H01L 21/561; H01L 21/568; H01L 23/5384; H01L 23/544; H01L 22/12; H01L 25/0652; H01L 25/18; H01L 2223/54426

(57) ABSTRACT

A method of forming a packaged multichip module includes molding a set of chips in a medium, mapping a position and orientation of the chips, forming an interconnect substrate. The forming of the interconnect structure including patterning a first interconnect layer to form a first plurality of patterned vias that each have an opening that is configured to connect with an interconnect formed on the chips based at least in part on the position and orientation information, and bonding the interconnect substrate to the multichip module. The bonding includes positioning and aligning the interconnect substrate to the chips such that the interconnects are aligned with the first plurality of patterned vias and attaching a stacked chip to the multichip module via the interconnect substrate, wherein interconnects of the stacked chip are electrically coupled to conductive layers formed in the first plurality of patterned vias of the first interconnect layer.

### BACKGROUND

### Field

Implementations of the present disclosure relate to apparatus, systems, and methods of digitalized interconnect redistribution enabled chiplet packaging, for example to provide a better area and line input/output density than a 2.5D interposer method, 2D fan-out packaging method, and 2.3D silicon bridge method

### Description of the Related Art

Electronic devices, such as are included in tablets, computers, copiers, digital cameras, smart phones, control systems, and automated teller machines, among others, often include integrated circuit die(s) for some desired functionality. A heterogeneous integration module (HIM) (which may also be referred to or be a type of multi-chip module (MCM)) is a type of microelectronics device that integrates multiple different chips, materials, components, and/or technologies into a single compact package. This approach allows designers to create more complex and powerful systems by integrating different components, without the need for full system-on-chip integration. For example, this type of device aims to provide a high level of functionality and performance while also reducing the overall size, cost, and complexity of the system. HIMs devices are commonly used in a wide range of applications, including smartphones, wearable devices, and internet of things (IoT) devices, as well as in various fields such as telecommunications, computing, and robotics. They are designed to overcome the limitations of traditional microelectronics devices, which often rely on a single technology or material, by bringing together complementary components and technologies in a single, integrated package. Some examples of HIMS devices include multi-layer microelectronics packages, system-in-package (SiP) devices, and 2D and 3D integrated circuits (3D ICs). These devices can offer improved performance, higher functional density, and better thermal management compared to traditional microelectronics devices. However, combining different components into a single component package can lead to alignment and other integration issues, requiring relatively larger interconnect pitch, resulting in higher interconnect resistivity, or both.

### SUMMARY

According to one or more embodiments, a method of forming a packaged multichip module, includes molding a set of chips in a medium, mapping a position and orientation of the chips within the set of chips that are molded in the medium, forming an interconnect substrate. The forming the interconnect substrate including patterning a first interconnect layer to form a first plurality of patterned vias that each have an opening that is configured to connect with an interconnect formed on the chips within the set of chips based at least in part on the position and orientation information detected during the mapping and bonding the interconnect substrate to the multichip module, wherein bonding includes positioning and aligning the interconnect substrate to the molded set of chips such that the interconnects of each chip within the set of chips are aligned with the first plurality of patterned vias formed in the interconnect substrate and attaching a stacked chip to the multichip module via the interconnect substrate, wherein interconnects of the stacked chip are electrically coupled to conductive layers formed in the first plurality of patterned vias of the first interconnect layer.

According to one or more embodiments, a method for forming a packaged multichip module includes disposing an interconnect substrate on a multichip module of the packaged multichip module. The disposing of the interconnect substrate including forming a first interconnect layer, patterning a first plurality of patterned vias through the first interconnect layer and the interconnect substrate so that each have an opening that is configured to connect with an interconnect formed on each chip of a set of chips of the multichip module based at least in part on position and orientation information detected during a mapping of alignment marks formed on each chip in the set of chips, forming a first plurality of metal interconnects in the first plurality of patterned vias, and bonding the interconnect substrate to the multichip module, wherein bonding comprises positioning and aligning the interconnect substrate to a molded set of chips such that the interconnects of each chip within the set of chips are aligned with the first plurality of patterned vias formed in the interconnect substrate.

According to one or more embodiments a packaged multichip module includes a set of chips molded in a medium, each chip having at least one alignment mark and a plurality of interconnects, an interconnect substrate bonded to the set of chips. The interconnect substrate including a first interconnect layer disposed over a base substrate comprising a first plurality of patterned vias that are patterned based at least in part on position and orientation information detected during a mapping of the alignment marks and the plurality of interconnects, a second interconnect layer disposed over the first interconnect layer comprising a first contacting surface formed on one side of the second interconnect layer comprising a first plurality of metal interconnects that match a pattern of the first plurality of patterned vias and a second contacting surface formed on a second side of the second interconnect layer comprising a second plurality of metal interconnects that are configured to connect with an interconnect formed on a stacked chip, and a stacked chip attached to one or more of the chips of the multichip module via the interconnect substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic view of a portion of a multichip module comprising an electrical or DSP chip according to one or more embodiments.

FIGS. 2A-2M illustrate cross-sectional and top views following a series of operations to form a multichip module according to one or more embodiments.

FIGS. 3A-3D illustrate cross-sectional views of a packaged multichip module according to one or more embodiments.

FIG. 4 is a flow diagram for forming a packaged multichip module according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

A multichip module (MCM) (or heterogeneous integration module (HIM)) may incorporate a number of semiconductor devices formed on or in a substrate (e.g., chips or chiplets). Examples of interconnection types used for HIMs include 2D fan-out type, 2.3D silicon bridge type, and 2.5D performance gap type.

A 2D fan-out packaging is a type of chip packaging technology that allows multiple chips or dies to be integrated onto a single package using a 2D layout. In this approach, the dies are mounted on a substrate, which is then molded with an insulating material to create a flat surface. The substrate is then etched to create a pattern of electrical interconnects, which connect the dies to each other and to the package's external pins. This packaging technique may allow for increased integration density and reduced form factor, as well as improved thermal performance due to the use of a thin and uniform package. Additionally, 2D fan-out packaging can offer better electrical performance compared to traditional packaging methods such as wire bonding, as the shorter interconnects and reduced parasitics can result in faster signal propagation and lower power consumption.

2.3D Si Bridge packaging is a type of semiconductor packaging technology that enables the integration of multiple dies or chips on a single package using a 2.5D or 3D layout. This approach involves using a silicon interposer or “bridge” that provides high-density electrical connections between the dies and other components, such as memory or sensors. In a 2.3D Si Bridge package, the interposer is thinned down to reduce the distance between the dies and minimize electrical parasitics, resulting in improved performance and power efficiency. This approach can also enable the use of heterogeneous integration, where different types of dies or technologies can be integrated on the same package. 2.3D Si Bridge packaging can offer a range of benefits, including increased performance, higher integration density, reduced power consumption, and improved thermal management, making it an attractive solution for high-performance computing, Al, and other advanced applications.

A multichip module that uses a 2.5D interposer is a type of electronic package that combines multiple chips or dies, that each may be fabricated using different processes and technologies, into a single module. In a 2.5D module, the individual dies are mounted on a silicon or organic interposer, which serves as a bridge between the dies and provides electrical and thermal connections.

In some cases, 2D fan out (X-Y) line space limits are at (2/2 um-5/5 um), which is typically not far from the line patterning capability of a system, but may present concerns of long-term reliability (e.g., on an organic dielectric) due to wafer/substrate global coefficient of thermal expansion (CTE) mismatch by and between one or more wafers and the substrate, CTE being the measure of the ability of a material to expand or contract with temperature changes. This problem may be especially acute for cross multi-die space areas.

In some cases, 2.3D (silicon (Si) Bridge) and 2.5D interposer type approaches use solder bumps (e.g., copper pillar (Cu-Pillar) solder bumps). Such solder bumps are typically associated with a higher electrical resistance than a direct Cu junction. The input/output area density is limited by solder bump pitch.

Implementations of the present disclosure relate to apparatus, systems, and methods of digitalized interconnect redistribution enabled chiplet packaging, for example to provide a better area and line input/output density than a 2.5D interposer method, 2D fan-out packaging method, and 2.3D silicon bridge method. It is also believed that the disclosed packaging structure and methods provided herein will also provide a lower electrical resistance than 2.5D & 2.3D packaging and better packaging process-induced stress management from a localized direct CTE-compatible RDL stack scheme from traditional 2-D packaging.

One or more embodiments disclosed herein includes a method of forming a multichip module, including printing or forming a set of alignment marks on a set of chips to be integrated into a multi-chip module, each chip having at least one alignment mark, molding the set of chips in a medium to secure each chip relative to each other chip, mapping each alignment mark of for a corresponding chip of the set of chips that are molded in the medium. The method further includes forming and bonding an interconnect substrate including a first interconnect layer having a plurality of vias that are based at least in part on the mapping, and at least one additional interconnect layer including first interconnects tailored to the patterning of the vias of the first interconnect layer on a first surface and second interconnects on a second surface tailored to mate with interconnecting features (e.g., pads, vias, traces, pins, etc.) formed in chips that are to be attached to the multichip module. For ease of discussion the term interconnect, die interconnect, or chip interconnect are often used herein to generally describe an interconnecting feature formed on a chip.

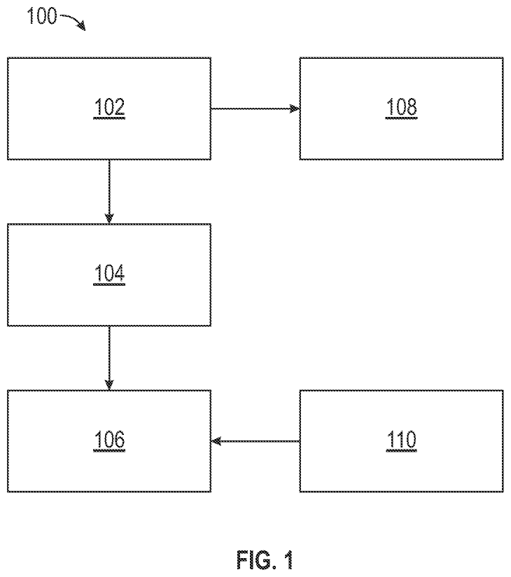

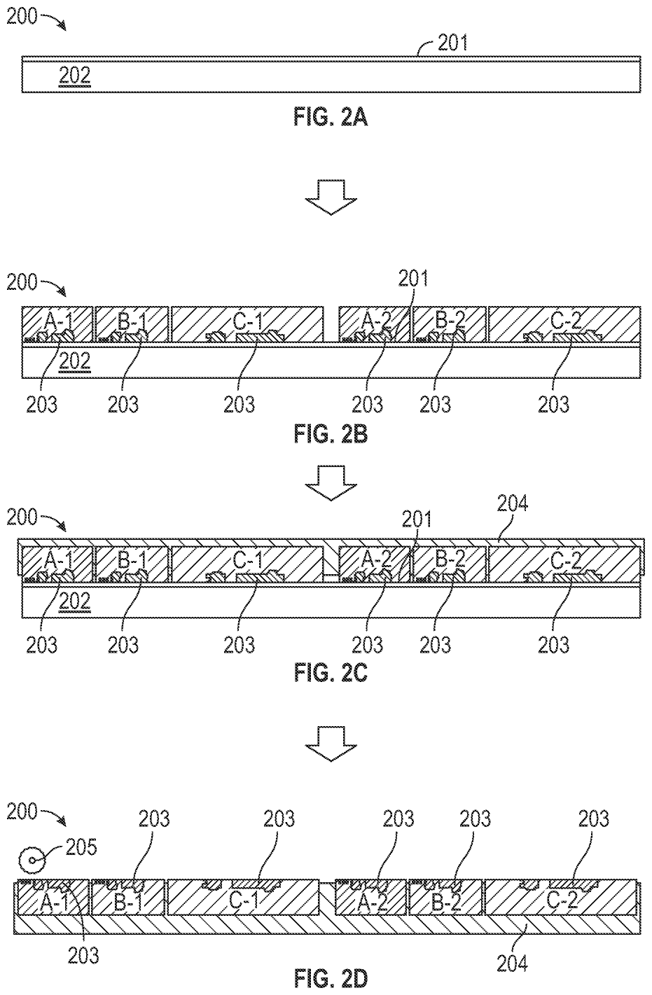

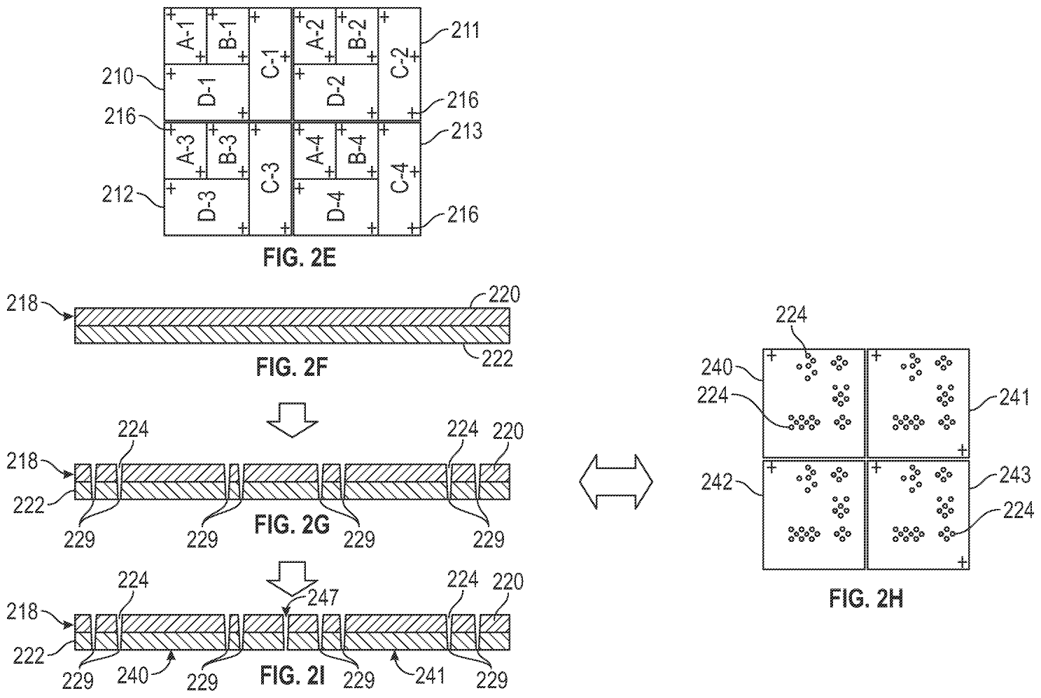

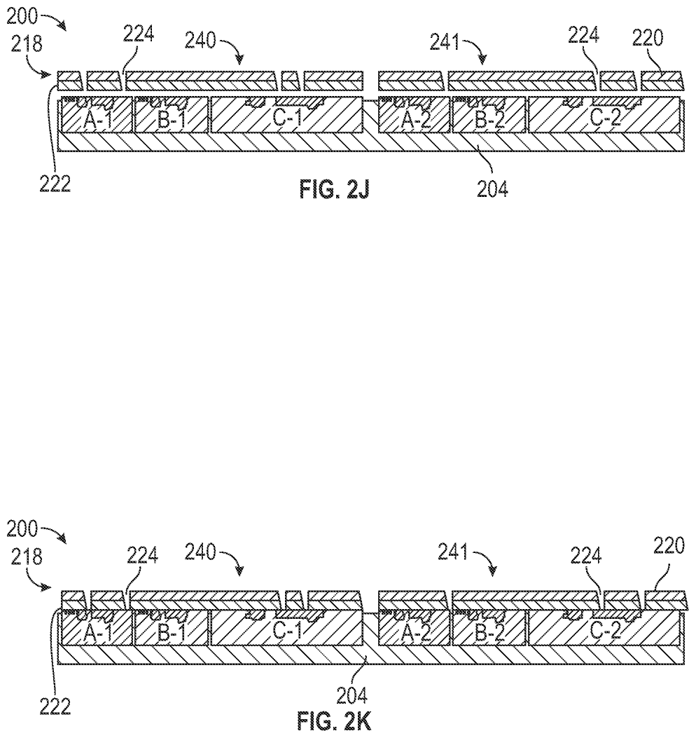

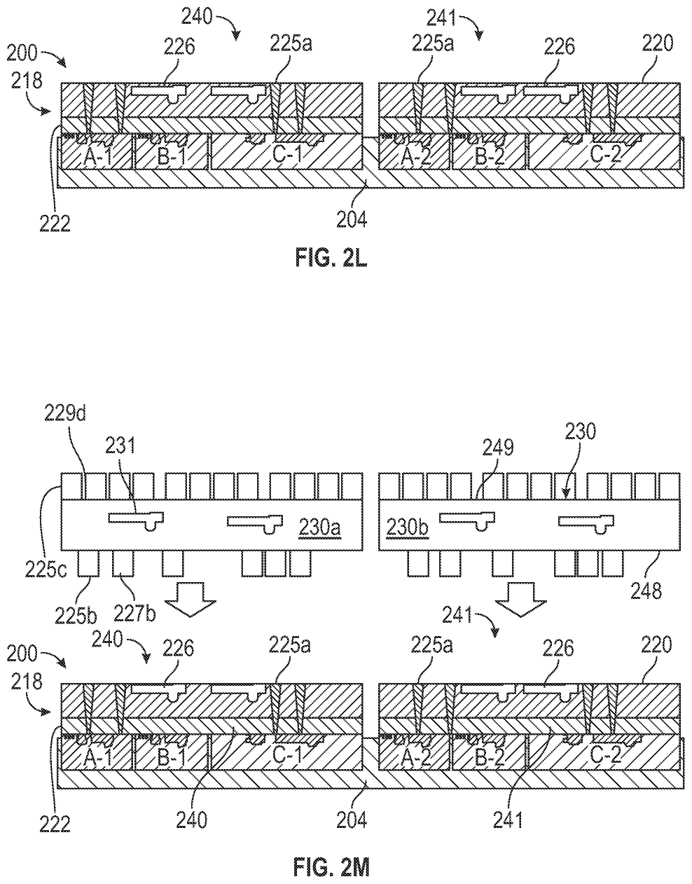

FIG. 1 is a schematic view of a portion of a multichip module 100 comprising an electrical or a digital signal processing (DSP) chip 102 according to embodiments. In one example, the electrical or DSP chip 102 may be connected by a plurality of optical waveguides or electrical trace interconnects to an integrated circuit (IC) chip 108 and an electronic integrated chip (EIC) 104, which all are formed in or disposed on a medium (i.e., a fill material 204 in FIGS. 2C-2D, and 2J-2K). In one or more examples, the IC chip 108 may comprise a DSP chip or a processor. In one example, a photonic integrated interconnect (PIC) unit 106 is attached to the multichip module 100. In one example, the PIC unit 106 is coupled to the EIC chip 104, the electrical or DSP chip 102, and/or the IC chip 108. In an embodiment, the PIC unit 106 is directly coupled to the EIC chip 104. In one example, the EIC chip 104 is generally used to assist with operations performed by the PIC unit 106. In one embodiment, the EIC chip 104 is operably connected to the PIC unit 106 to assist the PIC unit with various electrical functions.

In an embodiment, the electrical or DSP chip 102 may include any high-density chip having a high I/O pin count. In one example, the high-density chip has between 100 and 2000 I/O pins or up to and greater than 2000 I/O pin counts. Examples of electrical or DSP chips 102 include but not limited to data center SWITCH chips, artificial intelligence (AI) chips, and the like.

The PIC unit 106 includes a fiber connector region 110 configured to be coupled to a fiber connector for removably connecting a fiber cable to the PIC unit 106. In an embodiment, the fiber cable may be plugged into the fiber connector to operably connect the fiber cable to the chips of the multichip module 100. In an embodiment, the PIC unit 106 is configured for connecting fiber cables of the fiber connector region 110 including, but not limited to, single-mode fiber optic cables having 9 micron fiber core diameters. The fiber connector of the fiber connector region 110 may further include a plurality of optical fibers to operably connect fiber cables having between 1 to 74 fiber cores, 74 to 148 fiber cores, and up to and greater than 148 fiber cores to the PIC unit 106.

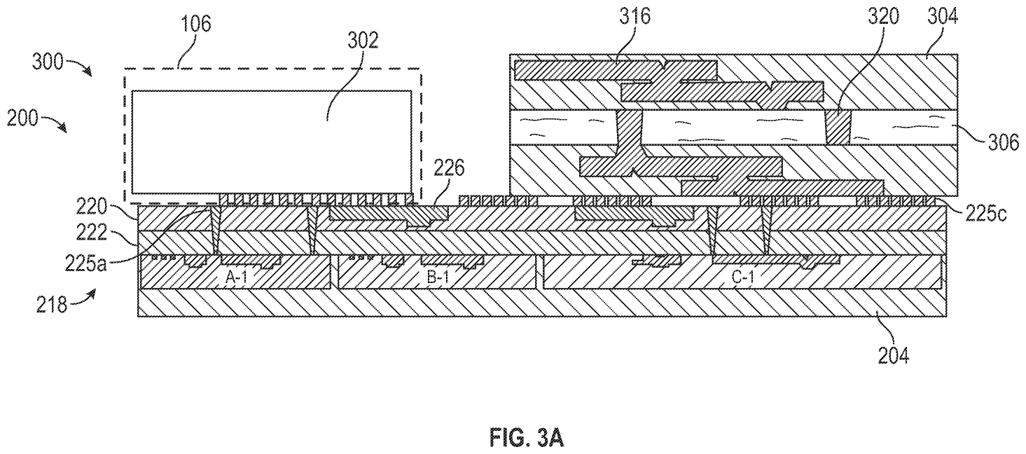

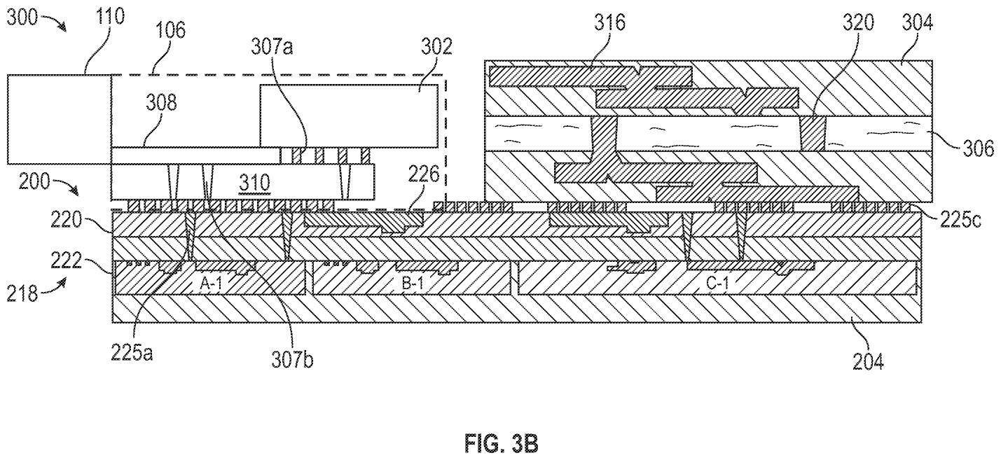

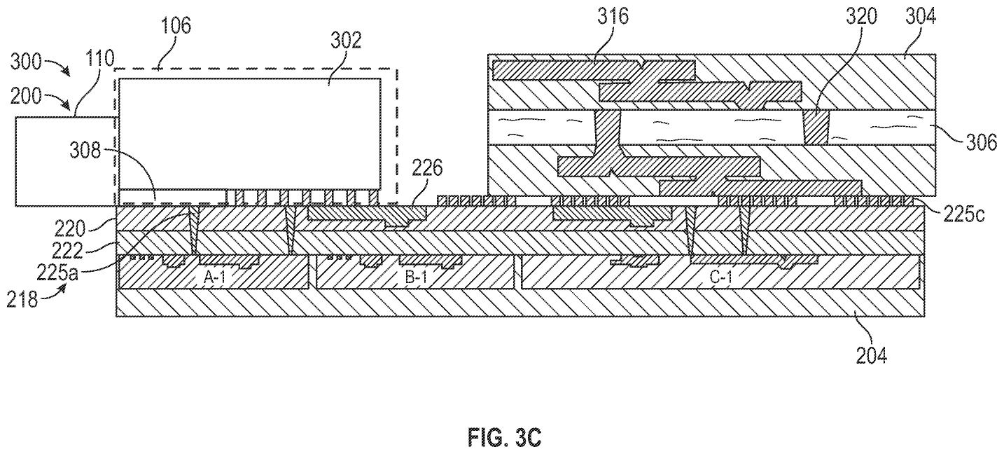

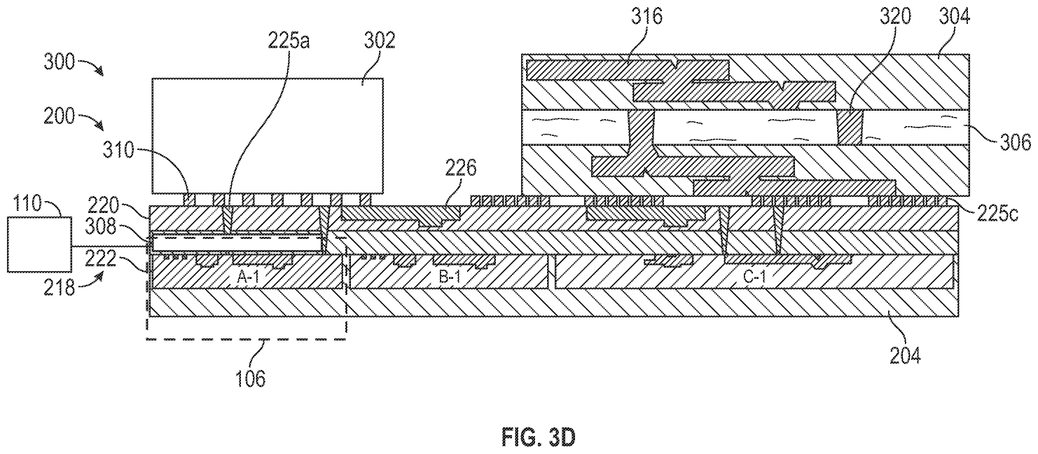

In an embodiment, the PIC unit 106 in the multichip module 100 is configured to transmit signals between the electrical or DSP chip 102 and the fiber cable of the fiber connector region 110 connected to the PIC unit 106. In one example, the PIC unit 106 includes a chip 302, such as an optical transceiver integrated circuit (SiPho chip). In one example, the chip 302 is mounted directly onto the multichip module (FIG. 3A). In another example, the PIC unit 106 includes a photonic glass layer (PGL) substrate 310 and the chip 302 is coupled to the multichip module 100 via the PGL substrate 310 (FIG. 3B). In another example, the PIC unit 106 includes a waveguide 308 and the chip 302 is coupled to the multichip module 100 via the waveguide 308 (FIG. 3C). In another embodiment, the PIC unit 106 includes the chip 302 and is included in the fill material 204 (FIG. 3D). These various configurations will be discussed in more detail below. In an embodiment, the chip 302 in the PIC unit 106 operates to convert electrical signals to optical signals, and vice versa.

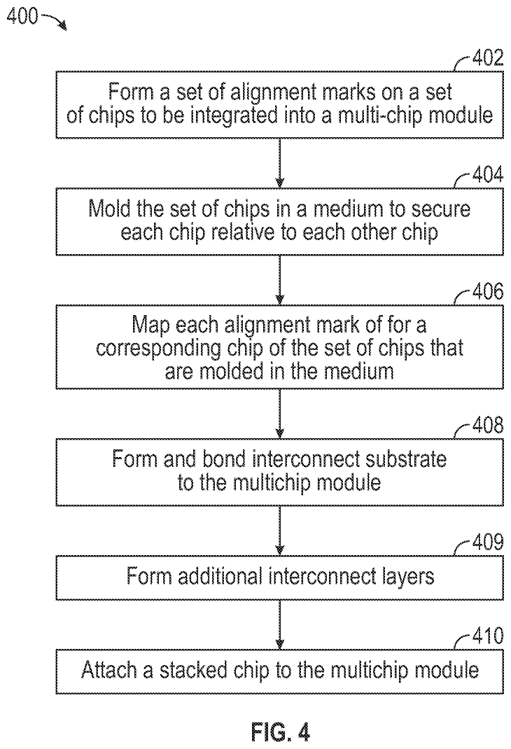

FIGS. 2A through 2M depict cross-sectional and top views following a series of operations used to form a multichip module 200 (which may also be or be referred to as a HIM herein). FIG. 4 is a flow diagram for forming a packaged multichip module.

In some embodiments, the multichip module 200 includes an interconnect structure and associated semiconductor devices (e.g., chiplets, including Active, Passive, or Electrical path chiplets) during formation of the multichip module. In some examples, the formed multichip module 200 may be or be referred to as digitalized interconnect redistribution enabled chiplet packaging.

At operation 402, a set of alignment marks 216 are formed on each chip of a set of chips to be integrated into multichip module 200 (FIG. 2E). In one example, each chip of the set of chips includes at least one alignment mark that is formed by a printing process.

At operation 404 each chip of the set of chips are positioned and then molded into a medium to secure each chip relative to each other chip. In one example, operation 404 includes the operations shown in FIGS. 2A-2E. In some embodiments, as explained above prior to molding the set of chips in the medium, the set of alignment marks 216 are formed on each chip of the set of chips (FIG. 2E). The alignment marks can be formed by a printing process, laser ablation process, scribing process, or other similar process.

FIG. 2A illustrates, in a side view, a temporary carrier 202 with tape 201 adhered thereto, following a first operation. In one or more implementations, the temporary carrier 202 can be either a wafer form or panel form, such as a silicon wafer or a glass substrate. In other implementations, the temporary carrier 202 is a carrier form, such as a polymeric carrier. In one or more implementations, the tape 201 is a two-sided tape, such as a thermal-release tape.

FIG. 2B illustrates, in a side view, a set of dies (chips) that are positioned on and adhered to the temporary carrier 202 using the tape 201, following a second operation. In one or more implementations, the set of dies includes at least three different types of dies. A first type of die (e.g., type A, including instances A-1 and A-2), a second type of die (e.g., type B, including instances B-1 and B-2), and a third type of die (e.g., type C, including instances C-1 and C-2) are adhered to the temporary carrier 202. In some implementations, each of the set of dies includes known good dies (KGDs) that include copper pads that are positioned so that they are ready for interconnection. In one example, each set of dies includes at least one EIC chip 104 (FIG. 1), a IC chip 108 (FIG. 1), and an electrical or DSP chip 102 (FIG. 1). In another example, each set of dies includes at least one of a SiPho chip of the PIC unit 106 (FIG. 1), a IC chip 108 (FIG. 1), and the electrical or DSP chip 102 (FIG. 1). In one example, each die that is type B is an EIC chip, each die that is type C is a DSP chip, and each die that is type A is an electrical or DSP chip 102. In another example, each die that is type A is a SiPho chip, each die that is type B is a DSP chip, and each die that is type C is an electrical or DSP chip 102.

The set of dies, including both the first type and second type, are adhered to the temporary carrier 202 (and tape 201) “face down” such that the pads or interconnects 203 of the dies contact face toward the temporary carrier 202. In some embodiments, the set of dies are arranged in separate die units across the surface of the temporary carrier 202, such as generally illustrated in FIG. 2E. As illustrated in FIG. 2E, in one example, four sets of four different types of die (e.g., A, B, C, and D) are arranged in a pattern within a region (i.e., a unit) of the surface of the temporary carrier 202. For example, a first set of dies including the dies A-1, B-1, C-1 and D-1 are arranged and positioned within a first die unit 210 of the surface of the temporary carrier 202, a second set of dies including the dies A-2, B-2, C-2 and D-2 are arranged and positioned within a second die unit 211, a third set of dies including the dies A-3, B-3, C-3 and D-3 are arranged and positioned within a third die unit 212, and a fourth set of dies including the dies A-4, B-4, C-4 and D-4 are arranged and positioned within a fourth die unit 213. For reference, FIG. 2E includes a view of an interconnection side of each of the dies, which are disposed against the tape 201 of the temporary carrier 202 illustrated in FIG. 2B. Although FIG. 2E illustrates four dies arranged in four different die units, this is for example purposes only, the quantity of die units and the quantity of dies within each die unit are not limited. Furthermore, although FIG. 2E illustrates that each type of die is positioned in a same location in each die unit (e.g., dies A-1 through A-4 are each located in the top left corner of their respective die unit), it is understood that the same type of die can be positioned in the same or different locations within each die unit.

FIG. 2C illustrates, in a side view, the set of dies adhered to the temporary carrier 202, where a fill material 204 has been applied. In one example, each dies of the set of dies are molded in the fill material 204 to secure each die relative to each other die. In one or more implementations, the fill material 204 covers the back and sides of each die of the set of dies. In one or more implementations, the fill material 204 is an epoxy (e.g., an epoxy molding compound (EMC)) that is applied to the set of dies adhered to the temporary carrier 202, and then cured, forming a molded set of dies. In some implementations, the EMC is then resurfaced to control the total thickness variation (TTV) of the molding. The resurfacing process can include performing one or more material removal steps, such as polishing, laser ablation, etching or other useful technique.

FIG. 2D illustrates, in a side view, the molded set of dies with the tape 201 and temporary carrier 202 removed, and thus, exposing the interconnection side of each of the dies. In one or more implementations, the temporary carrier 202 and tape 201 is debonded from the molded set of dies. The top face (e.g., the top metal side of the interconnection side) of the set of dies (e.g., chiplets) are then resurfaced, using a resurfacing process 205, to allow exposure of the contact pads as well as exposure of marks (e.g., individual die fiducial marks) of each die (e.g., chiplet). In one or more implementations, each die has a pre-layout alignment mark 216 (FIG. 2E). The resurfacing process 205 can include a chemical mechanical polishing (CMP) process, a grinding process, or other similar process.

FIG. 2E illustrates, in a top view, the molded set of dies with the tape 201 and temporary carrier 202 removed (e.g., debonded). As noted above, the molded set of dies are illustrated as four die units (210-213), each die unit includes one instance of a die from a first type of die (e.g., A-1 of A for the first die unit 210), one instance of a die from a second type of die (e.g., B-1 of B for the first die unit 210), one instance of a die from a third type of die (e.g., C-1 of C for the first die unit 210), and one instance of a die from a fourth type of die (e.g., D-1 of D for the first die unit 210). Each die has at least one alignment mark 216 that is used to define its position and orientation relative to other die within a die unit and/or with other die within other die units. Due to placement accuracy issues and movement of the die in prior performed processes, such as the processes performed during FIGS. 2B-2D, the relative position and orientation of each die within each die unit can vary die unit-to-die unit, at the state of the process sequence shown in FIG. 2E. In one or more embodiments, the alignment mark 216 is a “+” or “x” shape. Any suitable shape, type, or form of alignment mark, or combination of alignment marks, can be applied to the molded dies in other embodiments. In one or more embodiments, a die identifier is also applied, for example a barcode, or a QR code or other type of two dimensional barcode.

At operation 406, each of the alignment marks 216 of the molded set of dies are mapped by use of an optical inspection system that includes a camera and a system controller that includes a processor (CPU), nonvolatile memory and I/O components. For example, position and orientation information of the molded set of dies is determined based on the mapping of the alignment marks 216. The molded set of dies (i.e. chips) having the alignment marks 216 are scanned, analyzed and stored in memory of a system controller. Each chip (die) shift and orientation is scanned and recorded, for example in a graphic data system (GDS) file. In one or more embodiments, all digital map input and fiducial correction information is computed and consolidated at device level test as a file (e.g., GDS file) for separated interposer patterning use. As such, in some embodiments, the alignments marks 216 are die level alignment marks for use with a digital lithography technology (DLT) patterning process.

Some more of the advantages of this approach include that there is no reticle size limit on the interconnection pattern. Also, the digitalized interconnect redistribution substrate unit manufacturing process can be also decoupled from a single substrate manufacturing batch sequence and thus substrate units can be produced with other types of multiple-chiplet unit substrates as needed, which will provide additional manufacturing flexibility. In some embodiments, the recorded GDS file can also be reused in cases where the process needs to be repeated, or the data can be further pattern optimized through the substrate via interconnect and chiplet top metal patterning mapping. Moreover, it is easy to scale up the described operations to cover full multiple chiplet connection module, or both.

At operation 408, an interconnect substrate 218 (which may also be referred to as a direct interconnect land substrate (DILS)) is formed based on the scanned set of dies (i.e., the mapping). The interconnect substrate 218 is bonded to the multichip module 200 (i.e., the molded set of chips). The operations for forming the interconnect substrate 218 are illustrated in FIGS. 2F-2M.

FIG. 2F illustrates, in a side view, the interconnect substrate 218. In one or more embodiments, the interconnect substrate 218 includes a first interconnect layer 220 and a direct interconnect portion that includes the base substrate 222. In one example, the interconnect substrate 218 includes the first interconnect layer 220 which includes an epoxy material, an ABF material, a polyimide material, or other useful dielectric material, and the base substrate 222 comprises silicon (Si), silicon oxide or silicon dioxide (SiOx), glass, aluminum nitride (AlN), or silicon carbide (SiC). In one or more embodiments, the first interconnect layer 220 is a first redistribution layer (RDL) structure. The base substrate 222 may comprise silicon (Si), silicon oxide or silicon dioxide (SiOx), glass, aluminum nitride (AlN), silicon carbide (SiC), an organic material, or another type of suitable material. The base substrate 222 can be also include a built-in MIM capacitor, deep trench capacitor, inductor, resistor, or other active circuits. In some embodiments, the base substrate 222 is silicon, and the CTE is improved over conventional techniques that use other substrate materials. In one or more embodiments, the interconnect substrate 218 provides improved mechanical strength to support a fine pitched redistribution layer (RDL) (e.g., less than about 2/2 um, which is considered a typical multichip module (MCM) fanout limitation). In one or more embodiments, the interconnect substrate 218 provides relatively increased strength between dies without deformation, better thermal cycle reliability, or both. In some embodiments the interconnect substrate 218 includes one or more active circuit or passive components. In other embodiments the interconnect substrate 218 excludes includes active circuit and passive components. In one or more embodiments, the interconnect substrate 218 includes a DLT printing alignment mark and/or a laser scribed (but not limited to laser) barcode and alignment mark, for example for quality tracking and for a next level RDL stacking scheme or an extra added-on substrate packaging scheme.

In one or more examples, the base substrate 222 and the first interconnect layer 220 are etched in a pattern that is defined by the mapping process, as discussed in relation to operation 406. FIG. 2G illustrates, in a side view, the interconnect substrate 118 following an etching process to form a first plurality of patterned vias 224. In one example, the interconnect substrate 218 is etched (i.e. patterned) to provide the first plurality of patterned vias 224 therethrough, and in some cases alignment marks. The first plurality of patterned vias 224 may be etched through both the first interconnect layer 220 and the base substrate 222. The etching process can include the use of a digital lithography technology (DLT) tool that includes the use of one or more lasers and steering optics to form features in the interconnect substrate 218. DLT may also be referred to as “direct laser imaging” in some examples. DLT is a type of patterning process used in semiconductor and/or flat panel manufacturing to pattern and etch extremely small features in a substrate by use of a laser source. In DLT, the mask used to transfer the pattern onto the substrate is created digitally, using computer-aided design (CAD) software created from the graphic data system (GDS) file described above. As such, DLT may also be referred to as “maskless,” whether DLT uses a pattern or digital “mask.”

In one or more embodiments, the interconnect substrate 218 is etched according to a pattern to form the first plurality of patterned vias 224 that are positioned and aligned based on their relative position and orientation variation within each of the die units, as determined by the data (position and orientation information) collected from the scanning process (i.e., the mapping during operation 406) discussed above in relation to FIG. 2E. In one or more embodiments, the pattern can be inspected (e.g., using an automated optical inspection (AOI) system) to ensure alignment of the interconnect substrate 218 with the set of dies (e.g., check for 100% alignment with multiple dies).

FIG. 2H illustrates a top view of the first plurality of patterned vias 224 formed through the interconnect substrate 218 within an interconnect substrate unit that corresponds to each of the die units (e.g., die units 210-213 shown) that include the multiple die (e.g., four die) within each die unit that can have different placement orientations relative to each other within each die unit. For example, a first interconnect substrate unit 240 corresponds to the first die unit 210, a second interconnect substrate unit 241 corresponds to the second die unit 211, a third interconnect substrate unit 242 corresponds to the third die unit 212, a fourth interconnect substrate unit 243 corresponds to the fourth die unit 213. The position of the first plurality of patterned vias 224 created for each die within each interconnect substrate unit of the interconnect substrate 218 can vary unit-to-unit based on the variation in the position and orientation of each of the die within each unit within the molded set of dies. For example, each of the first plurality of patterned vias 224 are positioned within an opening 229 that is configured to connect with an interconnect 203 of a plurality of interconnects formed on each chip (i.e. die) in the multichip module 200 based on the mapping of the alignment marks 216. Stated differently, the first plurality of patterned vias 225 are positioned within an openings 229 that are aligned and positioned to form a connection with the interconnects 203 of each chip (i.e. die) in the multichip module 200 based on the position and orientation information of each chip in the multichip module 200.

In some embodiments, the first interconnect layer 220 and the direct interconnection portions (direct connection layers), such as the base substrate 222, are etched prior to attachment to the molded set of dies. In other embodiments, one or more interconnect layers can be formed on the first interconnect layer 220 of the interconnect substrate 218 that is attached to the molded set of dies at a later step in the processing sequence (e.g., see FIG. 2M).

In one or more embodiments, a base substrate thinning process is performed. In some embodiments, the base substrate thinning process is performed before the first plurality of patterned vias 224 are etched. In other embodiments, the base substrate thinning process is performed after the first plurality of patterned vias 224 are etched. In one or more embodiments, the base substrate thickness can be modulated.

In one or more examples, the interconnect substrate 218 is then diced into individual interconnect units, as shown by the formation of a separating feature 247. FIG. 2I illustrates, in a side view, a step where the interconnect substrate 218 has been diced into individual interconnect units so that each individual interconnect unit can be separately attached to each die unit of the molded set of dies. In one of more embodiments, the interconnect substrate 218 (e.g., a DILS) is diced into individual interconnect units by use of a DLT type process that forms the separating features 247. In some embodiments, dicing the interconnect substrate 218 into individual interconnect units and then bonding the individual interconnect units to portions of the molded set of dies will reduce the warpage and stress created in the individual die package units and individual die connections due to mechanical and thermal fluctuations created during subsequent processing steps. For example, the interconnect substrate 218 is diced into the first interconnect substrate unit 240, the second interconnect substrate unit 241, and so on. In one example, the first interconnect substrate unit 240 is configured to be affixed over first die unit 210, the second interconnect substrate unit 241 is configured to be affixed over the second die unit 211, and so on.

The interconnect substrate 218 may be aligned so that each individual interconnect unit is attached to the corresponding die unit. Stated differently the interconnect substrate 218 is aligned so that the interconnects 203 on each die (i.e. chip) in the molded set of dies (i.e., the set of chips) are aligned the first plurality of patterned vias 225. FIG. 2J illustrates, in a side view, the interconnect substrate 218 being aligned so that it can be attached to the molded set of dies. For example as further described above, each unit of interconnect substrate 218 (e.g., DILS unit) has an associated specific correction data (e.g., digital GDS data) that is used to position and align the pattern formed in the corresponding individual interconnect substrate units to a portion of the mating molded set of die. In some embodiments, because the correction data (e.g., GDS data) is digitalized, the correction data can be re-printed or re-optimized to form an improved interconnection structure. As noted above, the first interconnect substrate unit 240 is aligned over first die unit 210 and the second interconnect substrate unit 241 is aligned over the second die unit 211. Stated differently, the first interconnect substrate unit 240 is aligned with dies A-1, B-1, and C-1, and the second interconnect substrate unit 241 is aligned with dies A-2, B-2, and C-2.

The interconnect substrate 218 is then attached (bonded) to the molded set of dies (i.e., the multichip module 200) based on the alignment of the interconnect substrate units. FIG. 2K illustrates, in a side view, the interconnect substrate 218 being attached to the molded set of dies. As noted above, the first interconnect substrate unit 240 of the interconnect substrate 218 is attached to the first die unit 210 and the second interconnect substrate unit 241 of the interconnect substrate 218 is attached to the second die unit 211. In some embodiments, the pattern of first plurality of patterned vias are inspected by AOI to ensure alignment (e.g., 100% alignment) with the multiple dies of the set of dies. In some embodiments, the interconnect substrate 218 is diced as individual interconnect substrate units, which breaks the process inducing warpage and stress interference. The units of the diced individual interconnect substrate units are placed (e.g., via pick and place), and attached (e.g., using a die attach film (DAF) film or diffusion bond) on the assigned units (e.g., chiplets module) as an individual solid unit, for example, to decouple the global stress and warpage interference. According to one or more embodiments, following attachment, the openings 229 can be further processed to expose the metal contact surface positioned at the bottom of the first plurality of patterned vias 224. In some embodiments, a desmear process for the DAF film, or a plasma asher (plasma ashing) process can be used.

Next, the first plurality of patterned vias 224 are filled to form a first plurality of metal interconnects 225a. FIG. 2L illustrates, in a side view, the interconnect substrate 218 that has the first plurality of metal interconnects 225a formed therein. The first plurality of metal interconnects 225a, which are aligned with and configured to connect to the electrical connections of the die, can be formed by physical vapor deposition (PVD) process, an electroless plating process and/or an electroplating process. The first plurality of metal interconnects 225a fill the holes formed by the first plurality of patterned vias 224. In one or more embodiments, a copper barrier seed (CuBS) group of layers can be formed according to any suitable technique, and the first plurality of patterned vias 224 may be filled according to any suitable deposition technique (e.g., bulk fill on the barrier seed layer). Additionally, metalized traces 226 are formed in the first interconnect layer 220 of the interconnect substrate 218. In some embodiments, active devices (e.g., transistors), passive devices (e.g., resistors, capacitors), or both are formed on in the first interconnect layer 220.

In some embodiments, the connection between the interconnect substrate 218 (interposer) vias and the contacts of the chiplets (e.g., the pads of the chiplet, die or chip), which are not a solder interface, have a superior Cu line to Cu via interface connection (e.g., lowered resistivity) than prior conventional solder techniques. In some embodiments, the via density (input/output (I/O) area density is equal to or denser than prior techniques (e.g., a traditional 2.5D through substrate via (TSV) interposer approach). In some embodiments, the RDL line density is at least equal to Si interposer or Si bridge level, for example due to a similar rigid interconnect substrate (e.g., DILS substrate) flatness. However, in some embodiments, because the first plurality of metal interconnects 225a are positioned based on misalignments between each die of the sets of dies (i.e., the alignment marks) additional stacked chips used in packaging, such as a printed circuit boards (PCB), SiPho chips, and EIC chips (if not included in the molded set of dies) cannot be readily attached to the multichip module 200. Stated differently, the first plurality of metal interconnects 225a are not compatible (are out of alignment) with traces and/or other internal circuitry of stacked chips because the first plurality of metal interconnects 225a are positioned based on misalignment of the molded set of chips of the multichip module 200.

Therefore, at operation 409, additional interconnect layers having interconnects that are tailored to both the first plurality of metal interconnects 225a and the to be attached stacked chips may be formed over the first interconnect layer 220. In another example, the additional interconnect layers may be formed before the interconnect substrate 218 is attached to the molded set of dies. FIG. 2M illustrates, in a side view, a second interconnect layer 230 (e.g., second RDL type layer) added to the interconnect substrate 218 that has been attached to the molded set of dies. Although only a second interconnect layer 230 is added to the interconnect substrate 218, this is for example purposes only and multiple additional interconnect layers may be added to the interconnect substrate 218.

In one or more embodiments, the second interconnect layer 230 is an RDL structure. In other embodiments the second interconnect layer 230 is a C4/Cu pillar layer. The second interconnect layer 230 can be added after via formation of the interconnect substrate 218, for example for next level substrate integration. In one or more embodiments, prior to attaching the second interconnect layer 230, an inter-die fill can be applied to (formed on) the interconnect substrate 218. In some embodiments, the inter-die fill is spun on. In one example, the second interconnect layer 230 is deposited across the entire first interconnect layer 220 and is then singulated into separate portions configured to fit over each interconnect substrate unit. For example, the second interconnect layer 230 is singulated into a first portion 230a over the first interconnect substrate unit 240 and a second portion 230b over the second interconnect substrate unit 241. In another example, the first portion 230a and the second portion 230b are formed and attached separately.

In one or more embodiments, the second interconnect layer includes a first contacting surface 248 and a second contacting surface 249. The first contacting surface 248 comprises a second plurality of metal interconnects 225b. The first contacting surface 248 is formed on a first surface, such as a bottom surface, of the second interconnect layer 230. The second contacting surface 249 comprises a third plurality of metal interconnects 225c. The second contacting surface 249 is formed on a second surface, such as a top surface, of the second interconnect layer 230. The second and third plurality of metal interconnects 225b, 225c are formed on the second interconnect layer 230 so that stacked chips are able to be attached to at least one side of the multichip module 200. The second plurality of metal interconnects 225b are tailored (patterned) to the pattern of the first plurality of metal interconnects 225a and traces 226. The third plurality of metal interconnects 225c are tailored to match interconnects and traces of stacked devices (chips) such that the stacked devices (chips) can be easily and successfully attached to the multichip module 200 without the need to take into account the variation in the position of the die with the die unit. A fourth plurality of metal interconnects may be formed within the second interconnect layer 230. The fourth plurality of metal interconnects are each configured to form connections between the second plurality of metal interconnects 225b and the third plurality of metal interconnects 225c. The fourth plurality of metal interconnects 225d can be formed between the second plurality of metal interconnects 225b and the third plurality of metal interconnects 225c to allow communication between each set of dies (e.g., A-1, B-1, C-1, etc.) and the stacked chips attached to the multichip module 200. For example, one of the fourth plurality of interconnects is configured to couple interconnect 227b of the second plurality of metal interconnects 225b to interconnect 229c of the third plurality of metal interconnects 225c.

In one example, the second, third, and fourth pluralities of metal interconnects may also be formed using a DLT tool according to a file including die shift and orientation information (e.g., a second GDS file, or a second set of data in the GDS file associated with the previously formed interconnect layer and the to be attached stacked chip(s) (e.g. the first interconnect layer 220) or additional layers that are to be formed over the second interconnect layer 230. In one or more examples, as described above, more than one additional interconnected layers may be formed over the first interconnect layer 220. Each additional interconnect layer may include metal interconnects on each side of each additional interconnect layer that are tailored to continuously compensate for misalignments of the first plurality of metal interconnects 225a (due to misalignments between the molded set of chips). In the same manner described above, the top surface of the last (i.e., top) layer of the additional interconnect layers can have a pattern of metal interconnects tailored to be attached to a stacked chip that allow the molded set of chips to be in communication with the attached stacked chips.

Advantageously, each of the pluralities of metal interconnects of the interconnect substrate 218 can be used to form a connection to the chiplets (e.g., each chip of the molded set of chips) without a solder interface, which can provide a superior copper line to copper via interface (e.g., more reliable, lower resistivity). In some embodiments, after the second interconnect layer 230 is attached, metalized traces 231 can be processed (e.g., by a DLT tool) according to a file including die shift and orientation information (e.g., a second GDS file, or a second set of data in the GDS file associated with the previously formed interconnect layer (e.g. the first interconnect layer 220) or additional layers that are to be formed over the second interconnect layer 230. In some embodiments, the density can be equal to a silicon Si interposer or silicon bridge level approach due to a similar rigid DILS substrate flatness. According to one or more embodiments, the interconnect substrate 218 and layers can be extended to further layers using further DILI (e.g., including a direct interconnect substrate and RDL), each of which can include active or passive components, RDL, and so on. Each further layer may include a plurality of metal interconnects such as metal interconnects 225b-225d to allow chips to be attached to the multichip module 200 and communicate with the misaligned dies of the multichip module 200.

At operation 410 stacked chip(s) are attached to the multichip module 200, forming a packaged multichip module. FIGS. 3A-3D illustrate different ways to attach stacked chip(s) to the multichip module 200 to form a packaged multichip module 300. In some embodiments, as illustrated in FIGS. 3A-3D the packaged multichip module 300 includes multichip module 200. In one example, for example purposes, the first interconnect layer 220 of the interconnect substrate 218 includes both the first interconnect layer 220 and the second interconnect layer 230. Although only dies A-1, B-1 and C-1 are shown in FIGS. 3A-3D, this is for example purposes only and it is understood the each die unit of the multichip module 200 can be co-packaged in the same manner described in FIGS. 3A-3D.

Referring to FIG. 3A, in one example, a chip 302 and a printed circuit board 304 (PCB) are coupled to the multichip module 200. In one example, the chip 302 is a stacked chip such as an optical transceiver integrated circuit (SiPho chip) that is part of a PIC unit (i.e., PIC unit 106 in FIG. 1), die A-1 is an EiC chip, die B-1 is a DSP chip, and die C-1 is an SOC chip.

In some embodiments, as shown in FIG. 3A, the PIC unit 106 includes only the chip 302, such as a SiPho chip. The chip 302 may be coupled to the multichip module via a direct connection to the third plurality of metal interconnects 225c. Advantageously, while the first plurality of metal interconnects 225a are tailored the alignment marks 216 (i.e., the misalignments between the set of dies) the third plurality of metal interconnects 225c are tailored to the traces and/or internal circuitry of the chip 302 allowing for the chip 302 to be coupled to the multichip module 200 even if the set of dies are misaligned. Therefore, the interconnects of the chip 302 are electrically coupled to the conductive layers (i.e., the first plurality of metal interconnects 225a) formed in the first plurality of patterned vias 225. Stated differently, in one or more embodiments, the PIC unit 106 includes only chip 302. Advantageously, for electrical communication purposes, the SiPho chip (i.e., chip 302) is directly interconnected to an EIC chip 104 (i.e., die A-1) of the multichip module 200. Stated differently, the chip 302 has a direct interconnection to the EIC chip 104 (A-1) without use of any TSVs at the chip 302 or the EiC chip 104. The chip 302 is also connected to the IC chip 108 (B-1) and the electrical or DSP chip 102 (C-1) via the interconnect substrate 218.

Additionally, the PCB 304 may be attached to the multichip module 200 via the third plurality of metal interconnects 225c. In one example, the PCB 304 may be coupled to an SOC chip (die C-1) via the third plurality of metal interconnects 225c. In one example, the PCB may include an optional core substrate 306 (e.g., silicon or glass core substrate). The PCB 304 may include metal traces 316. Advantageously, while the first plurality of metal interconnects 225a are tailored to the alignment marks 216 (i.e., the misalignments between the set of dies) the third plurality of metal interconnects 225c are tailored to the metal traces 316 and/or internal circuitry of the PCB 304 allowing for a standardly configured PCB or PCB with a known configuration to be coupled to the multichip module 200 even if the set of dies are misaligned. In examples in which the PCB 304 includes a core substrate 306, the core substrate 306 may include metal interconnects 320 to allow connections between metal traces 316 of the PCB 304 on opposite sides of the core substrate 306.

Referring to FIG. 3B, in one example, the PIC unit 106 includes chip 302, a photonic glass layer (PGL) substrate 310, and a waveguide 308. In one example, the PGL substrate 310 is coupled to the multichip module 200 via the third plurality of metal interconnects 225c. Thus, as noted above, the interconnects of the chip 302 are electrically coupled to the conductive layers (i.e., the first plurality of metal interconnects 225a) formed in the first plurality of patterned vias 225. In one example, the chip 302 is an optical transceiver integrated circuit (SiPho chip) that is part of a PIC unit (i.e., PIC unit 106 in FIG. 1), die A-1 is an EiC chip, die B-1 is a DSP chip, and die C-1 is an SOC chip.

In some embodiments, as shown in FIG. 3B, the PIC unit 106 includes the chip 302, such as a SiPho chip, mounted near one end of the PGL substrate 310, the fiber connector region 110 is connected at an opposite end of the PGL substrate 310 from the chip 302, and a plurality of optical structures extend between the chip 302 and the fiber connector region 110. In one example, the chip 302 is connected to the PGL substrate 310 via metal interconnects 307a, and therefore, the multichip module 200 via metal interconnects 307b formed through the PGL substrate 310 and the third plurality of metal interconnects 225c. In an embodiment, each of the plurality of optical structures are configured to transmit light in either direction between the chip 302 and the optical structures. The light being transmitted through the optical structures can be either received from the waveguide 308 or received from one or more of a plurality of optical fibers within the fiber connector region 110 that a light signal source is in communication with during use. The chip 302 is typically configured to receive light (e.g., detect) transmitted through the optical structures and also emit light (e.g., transmit) into the optical structures in an effort to communicate with external devices connected through fiber connector region 110. The chip 302 can be configured to transmit light into the optical structures by at least the use of light emitters integrated into the chip 302, or by use of light emitters that are external to the PGL substrate 310. Additionally, the PCB 304 is coupled to the multichip module in the same manner described in FIG. 3A.

Referring to FIG. 3C, in one example, the PIC unit 106 includes chip 302, and the waveguide 308. Advantageously, as described in FIG. 3A due the chip 302 is directly connected to the multichip module 200 via the third plurality of metal interconnects 225c. Thus, as noted above, the interconnects of the chip 302 are electrically coupled to the conductive layers (i.e., the first plurality of metal interconnects 225a) formed in the first plurality of patterned vias 225. Additionally, the PCB 304 is coupled to the multichip module in the same manner described in FIG. 3A.

Referring to FIG. 3D, the PIC unit 106 includes the chip 302 and the waveguide 308, the PIC unit 106 is included in multichip module 200 (i.e., within the molded set of dies), and the waveguide 308 is embedded within the base substrate 222. Stated differently, in one example the type A dies (e.g., A-1 through A-4) are a SiPho chip. In one example, the fiber connector region 110 is coupled to the waveguide 308 via a wire. In examples where the type A dies are a SiPho chip, the chip 302 may comprise an IC chip and is attached to the multichip module 200 directly via the third plurality of metal interconnects 225c. Thus, as noted above, the interconnects of the chip 302 are electrically coupled to the conductive layers (i.e., the first plurality of metal interconnects 225a) formed in the first plurality of patterned vias 225.

What is claimed is:

1. A method of forming a packaged multichip module, comprising:
molding a set of chips in a medium;
mapping a position and orientation of the chips within the set of chips that are molded in the medium;
forming an interconnect substrate, comprising:
patterning a first interconnect layer to form a first plurality of patterned vias that each have an opening that is configured to connect with an interconnect formed on the chips within the set of chips based at least in part on the position and orientation information detected during the mapping; and
bonding the interconnect substrate to the multichip module, wherein bonding comprises positioning and aligning the interconnect substrate to the molded set of chips such that the interconnects of each chip within the set of chips are aligned with the first plurality of patterned vias formed in the interconnect substrate; and
attaching a stacked chip to the multichip module via the interconnect substrate, wherein interconnects of the stacked chip are electrically coupled to conductive layers formed in the first plurality of patterned vias of the first interconnect layer.

2. The method of claim 1, further comprising:
forming a second interconnect layer over the first interconnect layer; and
patterning the second interconnect layer to include a first contacting surface formed on one side of the second interconnect layer comprising a first plurality of metal interconnects that match a pattern of the first plurality of patterned vias and a second contacting surface formed on a second side of the second interconnect layer comprising a second plurality of metal interconnects that are configured to connect with an interconnect formed in the stacked chip.

3. The method of claim 2, wherein the first plurality of patterned vias are formed through both the first interconnect layer and a base substrate of the interconnect substrate.

4. The method of claim 1, wherein the stacked chip is attached directly to the interconnect substrate.

5. The method of claim 2, further comprising attaching a photonic glass layer (PGL) substrate to the second plurality of metal interconnects, and the stacked chip is attached to the multichip module via the PGL substrate.

6. The method of claim 2, further comprising attaching a printed circuit board (PCB) to the multichip module via the second plurality of metal interconnects.

7. The method of claim 6, wherein the PCB includes a core substrate.

8. The method of claim 1, wherein mapping each alignment mark of a corresponding chip of the set of chips comprises scanning and analyzing each alignment mark of the corresponding chip to determine an orientation and chip shift of the corresponding chip and storing the orientation and chip shift of the corresponding chip.

9. The method of claim 2, wherein the interconnect substrate further comprises a third plurality of metal interconnects in the second interconnect layer, the third plurality of metal interconnects connecting the first plurality of metal interconnects and the second plurality of metal interconnects.

10. A method for forming a packaged multichip module comprising:
disposing an interconnect substrate on a multichip module of the packaged multichip module, the disposing of the interconnect substrate comprising:
forming a first interconnect layer;
patterning a first plurality of patterned vias through the first interconnect layer and the interconnect substrate so that each have an opening that is configured to connect with an interconnect formed on each chip of a set of chips of the multichip module based at least in part on position and orientation information detected during a mapping of alignment marks formed on each chip in the set of chips;
forming a first plurality of metal interconnects in the first plurality of patterned vias; and
bonding the interconnect substrate to the multichip module, wherein bonding comprises positioning and aligning the interconnect substrate to a molded set of chips such that the interconnects of each chip within the set of chips are aligned with the first plurality of patterned vias formed in the interconnect substrate.

11. The method of claim 10, further comprising:
disposing a second interconnect layer over the first interconnect layer; and
patterning the second interconnect layer to include a first contacting surface formed on one side of the second interconnect layer comprising a second plurality of metal interconnects that match a pattern of the first plurality of patterned vias and a second contacting surface formed on a second side of the second interconnect layer comprising a third plurality of metal interconnects that are configured to connect with an interconnect formed in a stacked chip.

12. The method of claim 11, further comprising attaching the stacked chip to the multichip module via the third plurality of metal interconnects.

13. The method of claim 11, wherein the stacked chip is attached directly to the third plurality of metal interconnects.

14. The method of claim 11, further comprising attaching a photonic glass layer (PGL) substrate to the third plurality of metal interconnects and attaching the stacked chip to the multichip module via the PGL substrate.

15. The method of claim 11, further comprising attaching a printed circuit board (PCB) to the multichip module via the third plurality of metal interconnects.

16. A packaged multichip module, comprising:
a set of chips molded in a medium, each chip having at least one alignment mark and a plurality of interconnects;
an interconnect substrate bonded to the set of chips, the interconnect substrate comprising:
a first interconnect layer disposed over a base substrate comprising a first plurality of patterned vias that are patterned based at least in part on position and orientation information detected during a mapping of the alignment marks and the plurality of interconnects;
a second interconnect layer disposed over the first interconnect layer comprising a first contacting surface formed on one side of the second interconnect layer comprising a first plurality of metal interconnects that match a pattern of the first plurality of patterned vias and a second contacting surface formed on a second side of the second interconnect layer comprising a second plurality of metal interconnects that are configured to connect with an interconnect formed on a stacked chip; and
a stacked chip attached to one or more of the chips of the multichip module via the interconnect substrate.

17. The packaged multichip module of claim 16, wherein the stacked chip is attached directly to the second plurality of metal interconnects.

18. The packaged multichip module of claim 16, wherein a photonic glass layer (PGL) substrate is attached to the second plurality of metal interconnects and the stacked chip is attached to the multichip module via the PGL substrate.

19. The packaged multichip module of claim 16, further comprising a printed circuit board (PCB) to attached to the multichip module via the second plurality of metal interconnects.

20. The packaged multichip module of claim 16, wherein the first plurality of patterned vias are formed through both the first interconnect layer and the base substrate of the interconnect substrate.
